(19) United States
(12) Patent Application Publication
(10) Pub. No.: US 2003/0040174 A1
(43) Pub. Date: Feb. 27, 2003

(54) Method for preventing photoresist poisoning in semiconductor fabrication

(76) Inventors: Cher Huan Tan, Singapore (SG); Moitreyee Mukherjee-Roy, Singapore (SG); Pang Dow Foo, Singapore (SG)

Correspondence Address: CONLEY ROSE, P.C., P. O. BOX 3267, HOUSTON, TX, 77253-3267, US

(21) Appl. No.: 10/025,085

(22) Filed: Dec. 19, 2001

(30) Foreign Application Priority Data
Aug. 24, 2001 (SG) 200105179-6

(51) Int. Cl. H01L 21/4763; H01L 23/48; H01L 29/40

(52) U.S. Cl. 438/638; 438/694; 438/700; 257/758

(57) ABSTRACT

A method for photolithographic patterning in a via-first dual damascene process involving the use of a low-K dielectric material as an insulation layer on a wafer substrate during the fabrication of an integrated circuit is described. The method includes filling an aperture etched into an insulation layer on a wafer substrate with a fill-in material for isolating the insulation layer from a photoresist layer deposited thereafter and depositing a photoresist layer on the insulation layer. The method further includes exposing and developing the photoresist layer for providing a photoresist mask pattern for subsequent etching of the insulation layer; and removing the fill-in material from the aperture.

### FIELD OF INVENTION

The invention relates generally to integrated circuit manufacture. In particular, the invention relates to photolithographic patterning in which photoresist poisoning occurs during exposure and development of photoresist.

### BACKGROUND

During fabrication of microelectronic semiconductor devices on a wafer substrate to form an integrated circuit (IC), various conductive and insulation materials are deposited on the wafer substrate in a selective sequence for forming stacked layers of conductive and insulation materials.

Typically, a first conductive layer is disposed on a wafer substrate which is separated by a first level insulation, consisting of at least one insulation layer, from a second conductive layer stacked on top of the first level insulation. The second conductive layer may be in turn separated by a second level insulation, consisting of at least one insulation layer, from a third conductive layer stacked on top of the second level insulation. This alternating way of stacking the conductive and insulation materials continues for as many layers as is required in the IC. The conductive layers form a conductive pattern consonant with the IC design for interconnecting microelectronic semiconductor devices in the IC, in which the conductive layers are interconnected through the various levels of insulation by apertures or vias and trenches filled with conductive material.

To form the interconnections in the conductive pattern, photolithographic patterning is applied followed by etching for removing portions of the insulation layers for creating vias and trenches. During photolithographic patterning, a material that is light transmissible and photoreactive is deposited on the insulation layers to be etched. Ultra violet (UV) light is then selectively directed to portions of the photoresist layer using a mask, and the portions of the photoresist exposed to the UV light then undergo photochemical reactions. The photoresist layer is then developed whereby the soluble portions of the photoresist layer are dissolved and removed, therefore leaving behind a pattern of photoresist forming a mask for subsequence etching processes. A material known as bottom antireflective coating (BARC) is typically deposited beneath the photoresist layer for absorbing the UV light so as to minimise the reflection of the UV light back into the photoresist layer for ensuring uniform photochemical reactions in the photoresist layer.

Conventional approaches to laying the conductive pattern, more specifically the interconnecting vias and trenches, include the via-first dual damascene process. Such a process includes the steps described hereinafter.

In a first step, a first level insulation consisting of at least one insulation layer is deposited on an underlying semiconductor wafer substrate with a first conductive layer, and then depositing a first layer of BARC on the first level insulation. This is followed by the deposition of a first photoresist layer on the first layer of BARC, which is in turn followed by photolithographic exposure and development of the first photoresist layer for patterning a first photoresist mask on the various stacked layers. During the patterning process, an aperture is opened in the first photoresist layer over a position in the first level insulation where a via is required for providing interconnection between conductive layers.

In a second step, the first level insulation is subject to etching using the first photoresist pattern as a mask for forming the via and exposing the underlying first conductive layer, which is in turn followed by the stripping of the first photoresist layer and the first layer of BARC.

In a third step, a second layer of BARC is deposited on the first level insulation, followed by the deposition of a second photoresist layer on the second layer of BARC. This is in turn followed by photolithographic exposure and development of the second photoresist layer for patterning a second photoresist mask on the various stacked layers. During the patterning process, a wider aperture is opened in the second photoresist layer surrounding the via where a trench is required for providing interconnection between conductive layers.

In a fourth step, the first level insulation is further subject to etching using the second photoresist pattern as a mask for forming the trench, which is in turn followed by the stripping of the second photoresist layer and the second layer of BARC.

In applying the foregoing steps in the via-first dual damascene process, vias and trenches may be formed for interconnecting the conductive layers in an IC with microelectronic semiconductor devices.

Although the via-first scheme is most popular for dual damascene processing using conventional dielectric materials in the insulation layers, there are problems associated with the use of low-K dielectric materials in the insulation layers. The problems arise because of photoresist poisoning that occurs in relation to vias as shown in FIGS. 1a to 1c, in which FIG. 1a is a plan view of the photoresist layer pattern containing trenches exposed and developed using the conventional via-first scheme and FIGS. 1b and 1c are sectional views of the via during photoresist layer deposition and after development thereof, respectively. Photoresist poisoning causes photoresist layer pattern deformation 101 and 102 around and within the vias, in particular at isolated geometries or pattern edges of trenches 103 and 104 surrounding the vias. This happens because photoresist poisoning causes the photoresist to be undeveloped as a result of reactive substances out-diffusing from the low-K dielectric materials 106 to the photoresist 107 filling the vias during deposition of the second photoresist layer 108 in the foregoing third step of the via-first dual damascene processing. This leads to the incomplete removal of the photoresist filling the vias during the development of the second photoresist layer 108, thereby leaving behind photoresist residue 109. This in turn results in the incomplete etching of the insulation layers thereby generating the defects of undefined patterns around the vias which sometimes leads to the incomplete exposure of the first conductive layer 110.

Due to the difficulty in removing the photoresist residue which is caused by photoresist poisoning from interaction between the photoresist and low-K materials, alternative dual damascene processes such as the dual hard mask trench-first scheme may be used to replace the via-first scheme for the dual damascene process involving low-K dielectric materials. The dual hard mask trench-first scheme initially involves the generation of the trench patterns on the hard mask first, followed by the via photoresist patterning on the hard mask. Then the dual hard mask trench-first scheme involves etching the low-K dielectric materials to generate the damascene pattern and then removing the photoresist on top at the same time. In applying this scheme the photoresist poisoning problems may be alleviated, but the trade-off is that the dual damascene process becomes far more complex and therefore expensive as the number of steps increase.

There is clearly a need for an improved method for photolithographic patterning for facilitating the via-first dual damascene scheme of patterning conductive layers during the fabrication of microelectronic semiconductor devices for IC manufacture.

### SUMMARY

In accordance with a first aspect of the invention, there is described hereinafter in a via-first dual damascene process involving the use of a low-K dielectric material as an insulation layer on a wafer substrate during the fabrication of an integrated circuit, a method for photolithographic patterning. The method comprises the steps of filling an aperture etched into an insulation layer on a wafer substrate with a fill-in material for isolating the insulation layer from a photoresist layer deposited thereafter and depositing a photoresist layer on the insulation layer. The method further comprises the steps of exposing and developing the photoresist layer for providing a photoresist mask pattern for subsequent etching of the insulation layer; and removing the fill-in material from the aperture.

In accordance with a second aspect of the invention, there is described hereinafter in an integrated circuit manufactured using a via-first dual damascene process and having a low-K dielectric material as an insulation layer on a wafer substrate, a photolithographic pattern. The pattern comprises an aperture etched into an insulation layer on a wafer substrate filled with a fill-in material for isolating the insulation layer from a photoresist layer deposited thereafter. The pattern also comprises a photoresist layer deposited on the insulation layer, in which the photoresist layer is exposed and developed for providing a photoresist mask pattern for subsequent etching of the insulation layer.

### BRIEF DESCRIPTION OF THE DRAWINGS

Embodiments of the invention are described hereinafter with reference to the drawings, in which:

FIG. 1a is a plan view of a photoresist layer pattern containing trenches exposed and developed using a conventional via-first dual damascene scheme, and FIGS. 1b and 1c are sectional views of a via during photoresist layer deposition and after development thereof, respectively;

FIG. 2 is a flowchart depicting a method of photolithographic patterning according to an embodiment of the invention;

FIG. 3a is a plan view of a photoresist layer pattern containing trenches exposed and developed using a via-first dual damascene scheme involving the method of FIG. 2, and FIGS. 3b and 3c are sectional views of a via during photoresist layer deposition and after development thereof, respectively;

FIG. 4 is a sectional view of a via during photoresist layer deposition involving a method according to an alternative embodiment of the invention; and

FIG. 5 is a sectional view of a via during photoresist layer deposition involving a method according to an further alternative embodiment of the invention.

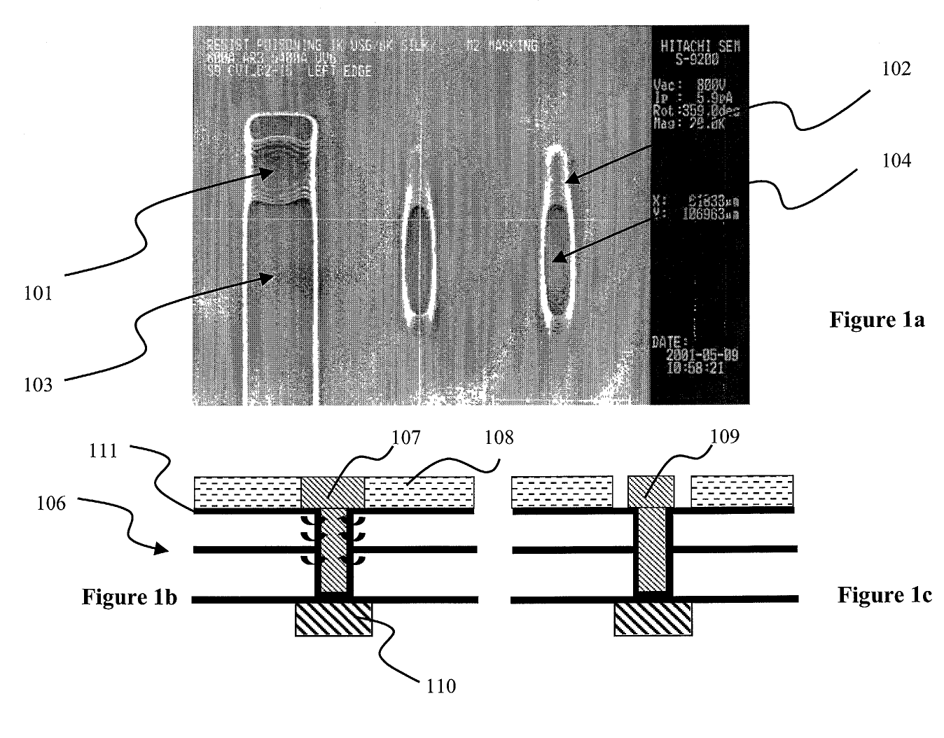

### DETAILED DESCRIPTION

Embodiments of the invention are described hereinafter for addressing the need for an improved method for photolithographic patterning for facilitating the via-first dual damascene scheme of patterning conductive layers during the fabrication of microelectronic semiconductor devices for IC manufacture.

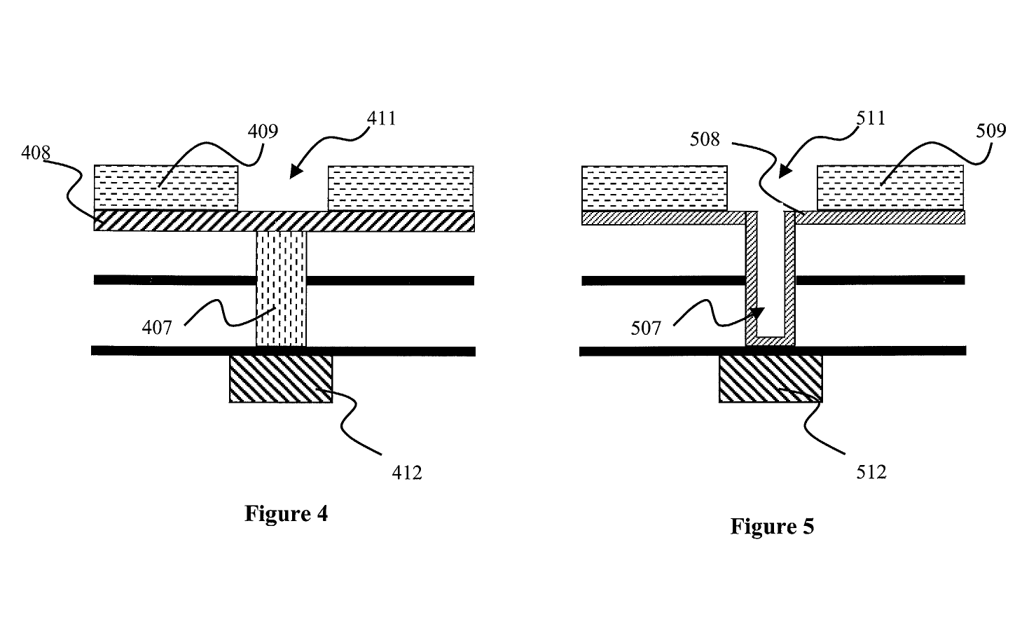

In order to alleviate the foregoing photoresist poisoning problems, it is proposed herein that an exposed photoresist is sufficiently isolated from the source of contamination, such as a low-K dielectric material, which may generate the caustic molecules in the photoresist. For example, full-filling a via with BARC that is used to planarize a wafer substrate and enhance the photolithographic process window, which is a window within which the process of photolithographic patterning is repeatable with acceptable results, is proposed herein for implementation in a method for photolithographic patterning according to an embodiment of the invention for alleviating photoresist poisoning in relation to the via-first dual damascene scheme involving low-K material. In the method, BARC is used to fully fill a via and therefore the exposed photoresist is sufficiently isolated by the full-fill BARC thereby preventing the diffusion of caustic molecules from the low-K dielectric material into the photoresist. Thus the photoresist may be completely developed for defining trench patterns. As a further example, any fill-in material which does not react with contaminants from the low-K dielectric material, for example any water soluble top antireflective coating such as aquaTAR, that is easily removed by using a solvent, for example de-ionised water, or other processes, may also be used to fully fill the via, as shown in FIG. 4, before depositing the BARC in a method for photolithographic patterning according to an alternate embodiment of the invention. This may improve the etching difficulties attendant on removing BARC from the via and still provide photoresist isolation from low-K dielectric material. As a yet further example, conformal BARC of thickness 800 to 2000 angstroms, preferably 1000 to 1200 angstroms, spun onto the wafer substrate may be deposited on the walls of the via, which is then subsequently filled with photoresist during photoresist deposition, as shown in FIG. 5, in a method according to a further alternate embodiment of the invention.

The advantages of the foregoing methods are manifold, especially since the methods may be used in accordance with the via-first dual damascene scheme. In the methods, lesser numbers of process steps than in the conventional trench-first hard mask dual damascene process are necessary because there is no need for the deposition and removal of hard mask and therefore the integration work is simpler. Also, the via-first process flow involves much lower cost compared with trench-first process flow. Furthermore, the methods involve simpler and better process controls in relation to alignment and etch profiles. This is because in the trench-first hard mask dual damascene process alignment of one pattern to another pattern and measurement of pattern overlay pose a challenge, and the smoothness of the edge and the verticalness of the side wall of the etched layers is simpler and easier to optimise in the case of the via-first dual damascene process. Still further, other than the alleviation of photoresist poisoning, applying the full-fill BARC or BARC over other fill-in materials to vias may provide a larger photolithographic process window in relation to photoresist profile and critical dimension control. The photoresist profile relates to the printed photoresist feature's edge smoothness and side wall verticalness, while the critical dimension control relates to how much control is gained on the printed or etched critical dimensions.

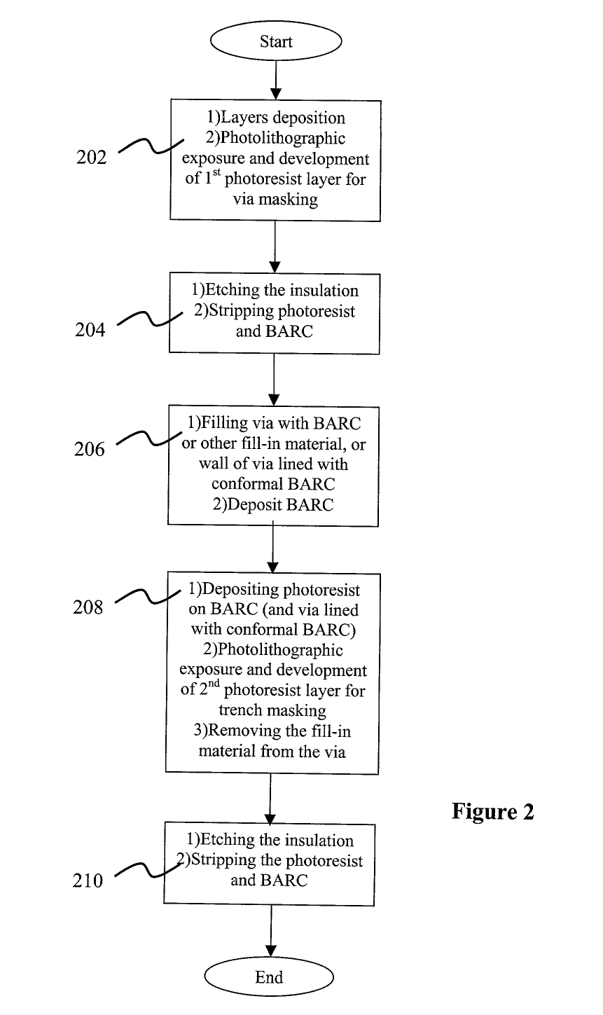

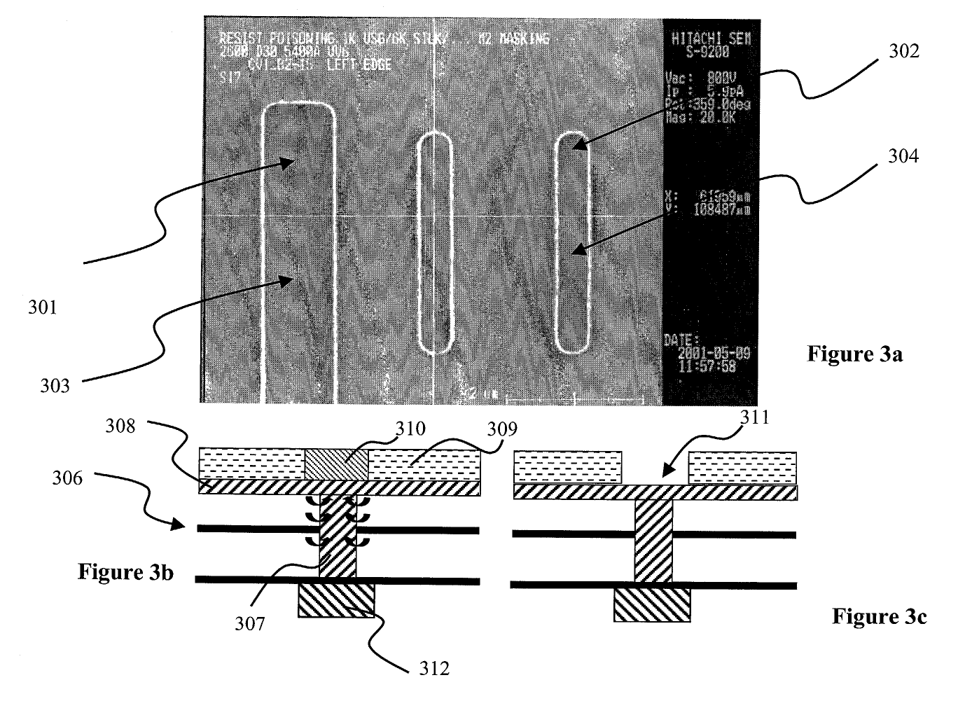

The methods are described generally with reference to a flowchart shown in FIG. 2. In a step 202, a first level insulation, for example consisting of two low-K dielectric layers (as shown in FIGS. 3b and 3c), is deposited on an underlying semiconductor wafer substrate with a first conductive layer, and then depositing a first layer of BARC on the first level insulation. This is followed by the deposition of a first photoresist layer on the first layer of BARC, which is in turn followed by photolithographic exposure and development of the first photoresist layer for patterning a first photoresist mask on the various stacked layers. During the patterning process, an aperture is opened in the first photoresist layer over a position in the first level insulation where a via is required for providing interconnection between conductive layers.

In a step 204, the first level insulation is subject to etching using the first photoresist pattern as a mask for forming the via and exposing the underlying first conductive layer, which is in turn followed by the stripping of the first photoresist layer and the first layer of BARC.

In a step 206, the via is filled with BARC or other fill-in material using a conventional deposition technique to full-fill the via for preventing the photoresist from filling the via and contacting the low-K dielectric layers in a next step 208. Alternatively, the walls of via is lined with conformal BARC and the remaining space in the via subsequently filled with photoresist in the next step 208. At the same time or separately depending on the BARC deposition technique, a second layer of BARC is deposited on the first level insulation and the full-filled via in some instances, and in other instances conformal BARC is deposited on the first level insulation only.

In the step 208, a second photoresist layer is deposited on the second layer of BARC. Where there is remaining space in the via after being lined with conformal BARC, the second photoresist layer also extends into the via. This is in turn followed by photolithographic exposure and development of the second photoresist layer for patterning a second photoresist mask on the various stacked layers. During the patterning process, a wider aperture is opened in the second photoresist layer surrounding the via where a trench is required for providing interconnection between conductive layers. The fill-in material in the via is removed in the case where the via is fully filled with BARC or other fill-in material, and in the case where conformal BARC is used the conformal BARC is stripped from the wall of the via.

In a step 210, the first level insulation is further subject to etching using the second photoresist pattern as a mask for forming the trench, which is in turn followed by the stripping of the second photoresist layer and the second layer of BARC.

In applying the foregoing steps in the via-first dual damascene process, vias and trenches may be formed for interconnecting the conductive layers in an IC with microelectronic semiconductor devices.

The problems attendant on the conventional via-first scheme for dual damascene processing using low-K dielectric materials in the insulation layers are alleviated using the foregoing steps. The photoresist poisoning that is alleviated is evidenced in FIGS. 3a to 3c, in which FIG. 3a is a plan view of the photoresist layer pattern containing trench exposed and developed using the via-first scheme involving the foregoing methods and FIGS. 3b and 3c are sectional views of the via during photoresist layer deposition and after development thereof, respectively. Photoresist poisoning that causes photoresist layer pattern deformation is absent from via positions 301 and 302 at isolated geometries or pattern edges of trenches 303 and 304 surrounding the vias. The photoresist poisoning that causes any photoresist in the via to be undeveloped as a result of reactive substances out-diffusing from the low-K dielectric materials 306 to the photoresist is prevented as the via is now filled with BARC 307 in the foregoing step 206 before the deposition of the second layer of BARC 308 and the second photoresist layer 309. Alternatively as shown in FIGS. 4 and 5 respectively, undeveloped photoresist in conventional situations is prevented as the via is now filled with any fill-in material 407 that does not react with the contaminants from the low-K material, or partially filled with photoresist 507 which is isolated from the low-K material by the conformal BARC 508 lining the walls of the via. This enables the complete removal of the exposed portion 310 of the photoresist for forming aperture 311, 411, or 511 in the photoresist layer 309, 409, or 509. This in turn enables the complete etching of the insulation layers thereby generating highly defined patterns around the vias that now leads to the complete exposure of the first conductive layer 312, 412 or 512.

In the foregoing manner, methods for photolithographic patterning according to embodiments of the invention for addressing the foregoing problems associated with conventional via-first dual damascene schemes involving low-K dielectric materials are described. Although only a number of embodiments of the invention are disclosed, it will be apparent to one skilled in the art in view of this disclosure that numerous changes and/or modification can be made without departing from the scope and spirit of the invention.

1. In a via-first dual damascene process involving the use of a low-K dielectric material as an insulation layer on a wafer substrate during the fabrication of an integrated circuit, a method for photolithographic patterning comprising the steps of:
filling an aperture etched into an insulation layer on a wafer substrate with a fill-in material for isolating the insulation layer from a photoresist layer deposited thereafter;
depositing a photoresist layer on the insulation layer;
exposing and developing the photoresist layer for providing a photoresist mask pattern for subsequent etching of the insulation layer; and
removing the fill-in material from the aperture.

2. The method as in claim 1, wherein the step of filling the aperture comprises the step of full filling the aperture.

3. The method as in claim 2, wherein the step of full filling the aperture comprises the step of full filling the aperture with antireflective coating.

4. The method as in claim 2, wherein the step of full filling the aperture comprises the step of full filling the aperture with a solvent based fill-in material.

5. The method as in claim 4, wherein the step of full filling the aperture with the solvent based fill-in material comprises the step of full filling the aperture with a water soluble fill-in material such as top antireflective coating.

6. The method as in claim 1, wherein the step of filling the aperture comprises the step of partially filling the aperture.

7. The method as in claim 6, wherein the step of partially filling the aperture comprises the step of lining the walls of the aperture.

8. The method as in claim 7, wherein the step of lining the walls of the aperture comprises the step of lining the walls of the aperture with conformal antireflective coating.

9. The method as in claim 8, wherein the step of lining the walls of the aperture with conformal antireflective coating comprises the step of lining the walls of the aperture with conformal antireflective coating to a thickness of 800 to 2000 angstroms.

10. The method as in claim 8, wherein the step of lining the walls of the aperture with conformal antireflective coating comprises the step of spinning onto the walls of the aperture the conformal antireflective coating.

11. In an integrated circuit manufactured using a via-first dual damascene process and having a low-K dielectric material as an insulation layer on a wafer substrate, a photolithographic pattern comprising:
an aperture etched into an insulation layer on a wafer substrate filled with a fill-in material for isolating the insulation layer from a photoresist layer deposited thereafter; and
a photoresist layer deposited on the insulation layer, in which the photoresist layer is exposed and developed for providing a photoresist mask pattern for subsequent etching of the insulation layer.

12. The pattern as in claim 11, wherein the aperture is fully filled.

13. The pattern as in claim 12, wherein the aperture is fully filled with antireflective coating.

14. The pattern as in claim 12, wherein the aperture is fully filled with a solvent based fill-in material.

15. The pattern as in claim 14, wherein the aperture is fully filled with a water soluble fill-in material such as top antireflective coating.

16. The pattern as in claim 11, wherein the aperture is partially filled.

17. The pattern as in claim 16, wherein the aperture is partially filled by lining the walls of the aperture.

18. The pattern as in claim 17, wherein the aperture is partially filled by lining the walls of the aperture with conformal antireflective coating.

19. The pattern as in claim 18, wherein the walls of the aperture is lined with conformal antireflective coating to a thickness of 800 to 2000 angstroms.

20. The pattern as in claim 18, wherein the conformal antireflective coating lining the walls of the aperture is spun onto the walls of the aperture.
